(19) United States
(12) Patent Application Publication
(10) Pub. No.: US 2024/0297264 A1
(43) Pub. Date: Sep. 5, 2024

(54) PHOTOVOLTAIC COMPONENT

(71) Applicant: FOXLED1 AG, Hünenberg (CH)

(72) Inventor: Peter SCHIBLI, Hünenberg (CH)

(73) Assignee: FOXLED1 AG, Hünenberg (CH)

(21) Appl. No.: 18/016,247

(22) PCT Filed: Jul. 16, 2020
(86) PCT No.: PCT/EP2020/070229

§ 371 Date: Jul. 18, 2023

(51) Int. Cl. H01L 31/054; H01L 31/048

(52) U.S. Cl. CPC H01L 31/0547; H01L 31/0488; H01L 31/0543

(57) ABSTRACT

The invention relates to a photovoltaic component (10) having an outer pane (11) and an inner pane (12). An energy generating layer (15) comprising a plurality of concentrator photovoltaic modules (20) is disposed between the outer pane 11) and the inner pane (12). The concentrator photovoltaic modules (20) have a condenser optic (40) as the primary optic, a partially transparent deflection optic (50) as the secondary optic, and a photovoltaic chip (22) integrated into a surface-mountable housing (30), the surface-mountable housing (30) having a transparent cover (36) and an integrated reflector (23) as the tertiary optic. The partially transparent deflection optic (50) is arranged between the photovoltaic chip (22) and the inner pane (12), and the transparent cover (36) faces the inner pane (12).

### FIELD OF INVENTION

The invention relates to a photovoltaic component.

The invention further relates to buildings and devices having a photovoltaic component and uses of the photovoltaic component.

### BACKGROUND

Photovoltaics is the conversion of light energy, usually from sunlight, into electrical energy using solar cells or photovoltaic cells.

The concentrator photovoltaic uses lenses and/or reflectors to concentrate sunlight onto photovoltaic cells. This allows a reduction in cell size. The energy conversion is usually performed by a special high-performance solar cell, in particular by means of high-efficiency multiple (multi-junction) solar cells made of, for example, III-V semiconductor materials.

Concentrator photovoltaic systems are categorized by the amount of their solar concentration, measured in “suns”. A distinction is made between low concentration systems, medium concentration systems and high concentration systems.

As a rule, increasing concentration also increases the complexity of the system. In particular, the requirements for cooling and optics increase.

Low-concentrator systems often have a simple booster reflector, but in some cases this can already increase solar electrical output by more than 30% over non-concentrator systems.

Highly concentrated systems, on the other hand, use more complex optical systems. These can consist, for example, of a Fresnel lens as the primary optic and a reflector as the secondary optic.

Solar mats are also known for large-area applications, which can be flexibly attached to various surfaces of buildings or devices. However, such solar mats, e.g. based on cadmium telluride or CIGS, have a limited efficiency.

Overall, it remains a challenge to integrate photovoltaic systems, especially concentrator photovoltaic systems, into buildings or devices in an efficient manner with high efficiency and to generate high solar output.

### Disclosure of the Invention

It is therefore an object of embodiments of the present invention to provide a photovoltaic component which avoids disadvantages of the known.

A further object of embodiments of the present invention is to provide a photovoltaic component that enables improved utilization of solar energy, and in particular does so in a cost-effective and efficient manner and with advantageous efficiency.

A first aspect of the invention relates to a photovoltaic component according to claim 1.

Accordingly, the photovoltaic component has an outer pane and an inner pane. An energy generating layer comprising a plurality of concentrator photovoltaic modules is arranged between the outer pane and the inner pane. The concentrator photovoltaic modules include a condenser optic as a primary optic, a partially transparent deflection optic as a secondary optic, and a photovoltaic chip integrated into a surface mountable housing. The surface mountable housing comprises a transparent cover and an integrated reflector as tertiary optic. The condenser optic is arranged between the outer pane and the photovoltaic chip, while the partially transparent deflection optic is arranged between the photovoltaic chip and the inner pane. The transparent cover and an entrance opening of the integrated reflector arranged under the transparent cover face the inner pane.

Such a photovoltaic component can be manufactured in an efficient and reliable manner. In addition, by integrating the energy-generating layer between the outer and inner panes, a long service life and reliability of the energy-generating layer can be achieved. Thus, the inner and outer panes protect the energy-generating layer from environmental influences.

According to embodiments of the invention, concentrator photovoltaic modules are thus integrated into the photovoltaic component. This enables a high efficiency, especially compared to solar foils made of, for example, cadmium telluride.

The integration of the photovoltaic chip in a surface-mountable housing enables efficient (pre) production of the photovoltaic chip in very large quantities. At the same time, a reflector is already integrated into the chip's housing. Such surface mountable modules, which are also referred to as SMD (surface mounted device) modules, can be assembled and processed in a particularly efficient and automated manner. In particular, the surface-mountable housings with the integrated photovoltaic chips and the integrated reflectors can be efficiently applied to the respective carrier material of the respective application, e.g. to a carrier foil, by means of re-flow soldering.

According to embodiments of the invention, the concentrator photovoltaic modules have three-level optics. As a result, increased efficiency can be achieved.

Here, the condenser optic is configured to focus or concentrate sunlight incident through the outer pane onto one or more deflection regions of the deflection optic. The deflection optic then deflects the light thus focused or collected into the integrated reflector, and the reflector in turn concentrates the sunlight deflected by the deflection optic onto the photovoltaic chip.

According to embodiments, the deflection optic is arranged between the inner pane and the surface-mountable housing with the photovoltaic chip, and the transparent cover of the surface-mountable housing faces the inner pane or, in other words, is directed downwards or is arranged on the side facing away from the sun. An entrance opening of the integrated reflector is provided under the transparent cover. The reflector concentrates or collects the deflected sunlight and directs it through an exit opening onto the photovoltaic chip.

Here, the terms “below” and “under” and “above” refer to the sun and the course of the incident sunlight.

According to embodiments, at least one of the one or more deflection regions is laterally offset from the surface mountable housing. This allows the incident sunlight to be directed past the surface mountable housing to the deflection optic and then redirected back to the transparent cover of the surface mountable housing. This can increase the efficiency.

According to one embodiment of the invention, the deflection optic is configured to perform a multi-stage deflection of the sunlight into the integrated reflector. In other words, the light is not deflected directly from the first deflection region on which the light focused by the condenser optic falls. Instead, one or more further deflections follow by means of the deflection optic before the deflected light is guided through the transparent cover into the integrated reflector.

In particular, the one or more deflection regions can be designed as reflective surfaces. The reflective surfaces can, for example, be reflective coatings of the deflection optic. According to embodiments, the reflective surfaces can be designed as specular surfaces.

According to embodiments, total internal reflection may be used to deflect light.

According to a further embodiment of the invention, the deflection optic may also comprise an optical waveguide. This can be designed in particular to receive the light reflected by a first deflection optic and to pass it on to the integrated reflector. In this case, total reflection can be used at the interfaces of the optical waveguide.

According to an embodiment of the invention, the photovoltaic component has a light transmission of more than 50%, in particular of more than 75%. This extends the areas of application of the photovoltaic component. In particular, the photovoltaic component can thus be used, for example, as a window or also for other applications in which the area behind or below the inner pane is or must be supplied with sunlight. The light transmission or transparency refers in particular to the spectral range visible to the human eye.

According to a further embodiment of the invention, the deflection region or the deflection regions of the deflection optic cover a maximum of 20%, in particular a maximum of 15%, of the horizontal cross-sectional area of the photovoltaic component. In particular, if the deflection regions are designed as reflective, in particular specular, and thus opaque or largely opaque surfaces, it can be achieved that the photovoltaic component is nevertheless partially transparent.

According to a further embodiment of the invention, the condenser optic of the concentrator photovoltaic modules have several condenser lenses which are arranged next to each other. According to embodiments of the invention, the condenser lenses are arranged in particular rotationally symmetrical to a central axis of the concentrator photovoltaic module. Such a module makes it possible to focus the sunlight on different regions of the deflector. This enables additional advantageous designs of the photovoltaic component.

According to a further embodiment of the invention, at least one of the condenser lenses is arranged at an angle, in particular a fifth angle, inclined with respect to a horizontal plane of the photovoltaic component. This enables an increased light yield and thus an increased efficiency. In particular, with such an embodiment of the invention, it is possible to align the at least two condenser lenses differently with respect to the elevation and thus to provide a condenser lens aligned for different sun angles in each case.

It should be noted here that the term horizontal plane of the photovoltaic component refers to the base region of the component and is thus intended to run in particular parallel to the inner and the outer pane. The term horizontal plane of the photovoltaic component is thus not necessarily intended to refer to the particular installation situation of the photovoltaic component. For example, if the photovoltaic component is installed vertically, e.g. as a window in a building, the horizontal plane of the photovoltaic component may be perpendicular to the floor of the building.

According to an embodiment, the photovoltaic component has a first condenser lens which is arranged inclined at the fifth angle with respect to the horizontal plane of the photovoltaic component and a second condenser lens which is arranged in or parallel to the horizontal plane of the photovoltaic component. In such an embodiment, the first condenser lens is intended in particular to optimally capture and focus the sunlight in the morning and in the afternoon and the second condenser lens is intended in particular to optimally capture and focus the sunlight at noon (solar maximum).

The outer pane and the inner pane preferably have high transmission.

According to an embodiment of the invention, the outer pane and/or the inner pane may be made of glass and thus be designed as a glass component. According to a further embodiment of the invention, the outer pane and/or the inner pane may consist of a plastic and thus be designed as a plastic component.

According to embodiments of the invention, a pane is generally used to designate sheet-like, in particular layer-like elements, which are in particular transparent or partially transparent. According to embodiments of the invention, a pane can thus also be referred to as a layer, in particular as a transparent or partially transparent layer. According to embodiments of the invention, a pane can have a wide variety of geometries adapted to the respective installation position. According to embodiments, a pane may in particular be rectangular or square. According to embodiments of the invention, a pane is in particular rigid or stiff.

According to another preferred embodiment of the invention, the housing has a recess forming a receiving tray with a recessed bottom portion for receiving the photovoltaic chip, the receiving tray having side walls with reflective regions forming the reflector.

According to an embodiment, the receiving tray has sidewalls with at least a first reflective region and a second reflective region, wherein the first reflective region is oriented at a first angle relative to a horizontal plane of the housing and the second reflective region is oriented at a second angle relative to the horizontal plane of the housing. The first angle is thereby different from the second angle.

A concentrator photovoltaic module designed in this way makes it possible to select the two different angles of the first reflective region and the second reflective region individually and to adapt them to the respective external conditions, in particular the respective orientation of the surfaces intended for installation and the respective solar exposure of the surfaces intended for installation. The first and the second reflective region form reflective surfaces which receive the sunlight via the transparent cover, reflect it and transmit it in the direction of the photovoltaic chip or concentrate it on the photovoltaic chip. Thus, the at least two reflective regions of the receiving tray form a reflector.

It should be noted here that the term horizontal plane of the housing refers to the base or bottom surface of the housing and, in particular, is intended to run parallel to the bottom surface of the housing. The term horizontal plane of the housing is thus not necessarily intended to refer to the particular installation situation of the housing. For example, when the housing is installed vertically in a building, the horizontal plane of the housing may be perpendicular to the floor of the building.

According to embodiments of the invention, the angles of the different reflective regions can thus be individually adapted to the respective installation situation in the building. In particular, the angles of the reflective regions can be adapted with respect to the elevation and/or the azimuth.

The different angles of the first reflective region and the second reflective region can increase the concentrating or reflecting effect and the efficiency of the concentrator photovoltaic module and the photovoltaic component in a simple, cost-effective and efficient manner.

The transparent cover of the surface mountable housing is preferably made of glass, in particular thin glass, e.g. Gorilla® glass or ultra-thin glass. According to another embodiment, the transparent cover may be made of plastic. According to preferred embodiments, the transparent or translucent cover allows the sunlight to pass as unhindered as possible into the reflector of the receiving tray and is therefore designed as a flat surface according to embodiments. In cross-section, the transparent cover is in particular rectangular, the thickness of the cover being selected to be as small as possible, for example 0.01 mm to 1 mm.

According to further embodiments, however, the transparent cover may also have a concave or convex shape and thus deflect and/or focus the sunlight.

According to embodiments, the photovoltaic chip can be designed as a single or as a multi-junction solar cell, in particular as a triple-junction or quadruple-junction solar cell. According to particularly preferred embodiments, the photovoltaic chip is a multi-junction solar cell made of a III-V semiconductor material, e.g. gallium arsenide (GaAs) or gallium antimonide (GaSb). In particular, the photovoltaic chip is implemented as a photovoltaic DIE, i.e., an unpackaged piece of a semiconductor wafer.

According to another advantageous embodiment of the invention, the photovoltaic component has a contacting layer with conductor tracks for contacting the concentrator photovoltaic modules or the photovoltaic chip. The contacting layer constitutes a printed circuit board or a carrier for the concentrator photovoltaic modules. The contacting layer can be formed in particular as a coating on the pane or as a flexible foil.

According to an embodiment of the invention, the concentrator photovoltaic modules and the condenser lenses are integrated in a plastic material, in particular in a transparent plastic material.

According to another preferred embodiment of the invention, the energy-generating layer is integrated by means of an outer and an inner composite layer of plastic between the outer and the inner pane. The composite layer can advantageously be a plastic foil, in particular made of PVB or EVA, or another plastic, e.g. PU or an acrylate or other plastic resin.

According to a preferred embodiment of the invention, the individual components of the photovoltaic component, in particular the surface-mountable housing, the concentrator photovoltaic modules and the contacting layer, are transparent or largely transparent.

According to another advantageous embodiment of the invention, a heat-absorbing foil is arranged behind the energy-generating layer. This can, for example, reduce heating of the building interior.

According to another advantageous embodiment of the invention, a heat dissipating foil is arranged behind the energy generating layer. This can also reduce heating of the building interior as well as heating of the photovoltaic component.

The heat-absorbing foil and/or the heat-dissipating foil can be arranged in particular under the inner pane or between the inner pane and the energy-generating layer.

According to a further advantageous embodiment of the invention, the contacting layer is designed as a heat-dissipating layer or foil. Here, in particular, the metallic conductor tracks can be used for heat dissipation.

According to an embodiment of the invention, the photovoltaic chip is arranged asymmetrically with respect to at least one vertical plane of symmetry of the housing. By means of such an asymmetrical arrangement of the photovoltaic chip in the housing, different angles of the first and the second reflective regions can be realized particularly efficiently and space-saving in the housing.

According to another embodiment of the invention, the first and second reflective regions are opposite each other with respect to a first vertical plane of symmetry of the photovoltaic chip. In other words, the first and second reflective regions are arranged on opposite sides of the photovoltaic chip.

Such an embodiment with opposing reflective surfaces with different angles allows for improved concentration of sunlight on the photovoltaic chip, especially for sunlight that is not incident parallel to the first vertical plane of symmetry of the photovoltaic chip.

According to an embodiment of the invention, the first angle and the second angle differ from each other by at least 10°, in particular by at least 20°.

Such different angles are particularly advantageous if the solar radiation does not fall perpendicularly or symmetrically with respect to the perpendicular on the concentrator photovoltaic module. In such conditions, such different angles enable an improved optical concentrating effect of the reflector.

According to an embodiment of the invention, the first reflective region and the second reflective region are formed as a reflective coating of the receiving tray. According to embodiments, such a coating can be applied to a base body of the surface mountable housing, for example, by means of a corresponding coating process.

According to a further embodiment of the invention, the first reflective region and the second reflective region are formed as a reflective foil.

According to embodiments, such a reflective foil, e.g. a metal foil, can be applied to the base body made of plastic, e.g. by means of a corresponding adhesive process.

According to further embodiments of the invention, the receiving tray has sidewalls with a third reflective region and a fourth reflective region. The third reflective region is oriented at a third angle relative to the horizontal plane of the housing, and the fourth reflective region is oriented at a fourth angle relative to the horizontal plane of the housing. According to further embodiments, the third angle is different from the fourth angle.

Such embodiments thus have four different reflective regions or reflective surfaces, each of which may be oriented at individual and different angles with respect to the horizontal plane of the housing.

Up to four different angles of the reflector can be used for the light or solar radiation to further improve the concentration effect or reflection effect of the reflector.

Accordingly, photovoltaic components according to embodiments of the invention can be manufactured both for vertical installation surfaces, e.g. for vertical windows, and thus installation surfaces that are unfavourably aligned with respect to solar radiation, and for installation surfaces that are arranged almost horizontally, such as for roof surfaces.

According to an embodiment, the third angle and the fourth angle differ by at least 10°, in particular by at least 20°.

According to embodiments of the invention, the housing is protected against solid foreign bodies and against liquids. According to embodiments, the housing has a scope of protection according to the International Protection (IP) code against solid foreign bodies of at least 5 and a scope of protection against liquids of at least 5. Such a protected housing ensures reliable and long-lasting operation even under adverse environmental conditions. In particular, the housing can be protected according to IP protection classes 65 to 68.

According to embodiments of the invention, the first reflective region, the second reflective region, the third reflective region and/or the fourth reflective region are each formed as a concave surface.

By means of such concave surfaces, the concentration effect of the reflective regions for the light or solar radiation can be increased.

According to other embodiments of the invention, the first reflective region, the second reflective region, the third reflective region, and/or the fourth reflective region are each formed as a planar surface.

This is particularly advantageous in terms of production technology.

According to embodiments of the invention, the housing has an integrated bypass diode, in particular a Schottky diode. The bypass diode can in particular be integrated into the base body, which can in particular be made of plastic. Such integration of the bypass diode in each individual package results in particularly high reliability. If a photovoltaic chip is defective or not fully functional, the current can be diverted via the bypass diode and the functionality of the overall system is not or hardly affected.

Another aspect of the invention relates to a building or device having one or more photovoltaic components according to any one of the preceding claims.

In particular, the device may be a vehicle, such as an automobile, a boat, a ship, a construction vehicle, an agricultural vehicle, a train, or an aircraft. The device may further be a container or a greenhouse.

Another aspect of the invention relates to the use of a photovoltaic component according to the above embodiments for installation or attachment in or to a building, a vehicle, a container, a greenhouse, as well as other devices.

Another aspect of the invention relates to the use of a photovoltaic component according to embodiments of the invention for mounting on agricultural land.

### BRIEF DESCRIPTION OF THE DRAWINGS

Further embodiments, advantages and applications of the invention result from the dependent claims and from the description now following on the basis of the figures. Thereby showing:

FIG. 1a a cross-sectional view of a energy-generating photovoltaic component according to an embodiment of the invention;

FIG. 1b a cross-sectional view of an energy-generating photovoltaic component according to another embodiment of the invention;

FIG. 2 an enlarged view of a concentrator photovoltaic module according to an embodiment of the invention;

FIG. 3 an enlarged view of a concentrator photovoltaic module according to an embodiment of the invention with a multi-stage deflection or reflection;

FIG. 4 a concentrator photovoltaic module with multiple condenser lenses;

FIG. 5 is another cross-sectional view of an energy-generating photovoltaic component 10 in an x-z plane according to an embodiment of the invention;

FIG. 6a a top view of a condenser optic according to FIGS. 1a, 1b, 2 and 3;

FIG. 6b is a top view of a condenser optic 40 shown in FIG. 4;

FIG. 6c a top view of a condenser optic according to FIG. 5;

FIG. 7 a cross-sectional view of a surface mountable housing according to an embodiment of the invention;

FIG. 8a a cross-sectional view of a surface mountable housing in an x-z plane;

FIG. 8b a cross-sectional view of the housing in a y-z plane;

FIG. 8c a top view of the housing in the x-y plane;

FIG. 9 a cross-sectional view of a surface mountable housing with electrical contacts;

FIG. 10a a photovoltaic component for predominantly horizontal installation in a device;

FIG. 10b a photovoltaic component with an inclined mounting position;

FIG. 10c a photovoltaic component for a predominantly vertical installation in a device;

FIG. 11 a top view of a photovoltaic chip array;

FIG. 12 a lens array according to an embodiment of the invention having a plurality of condenser lenses arranged in a plane;

FIG. 13 an array with a plurality of deflection optics arranged in a plane;

FIG. 14 shows a side view of a building or house with photovoltaic components;

FIG. 15 shows a top view of the building of FIG. 14;

FIG. 16 shows a side view of a house with a flat roof;

FIG. 17 a cross-sectional view of an energy-generating photovoltaic component;

FIG. 18 a cross-sectional view of an energy-generating photovoltaic component;

FIG. 19 an aircraft with multiple photovoltaic components integrated into the outer skin of the aircraft;

FIG. 20 a ship with multiple photovoltaic components disposed on the surface of the ship;

FIG. 21 a photovoltaic component which is located above an agricultural area;

FIG. 22 an automobile with integrated photovoltaic components;

FIG. 23 a greenhouse with integrated photovoltaic components according to embodiments of the invention;

FIG. 24a shows a cross-sectional view of an energy-generating photovoltaic component according to another embodiment of the invention; and

FIG. 24b shows an enlarged view of a concentrator photovoltaic module with prisms as deflection optic.

### WAY(S) TO CARRY OUT THE INVENTION

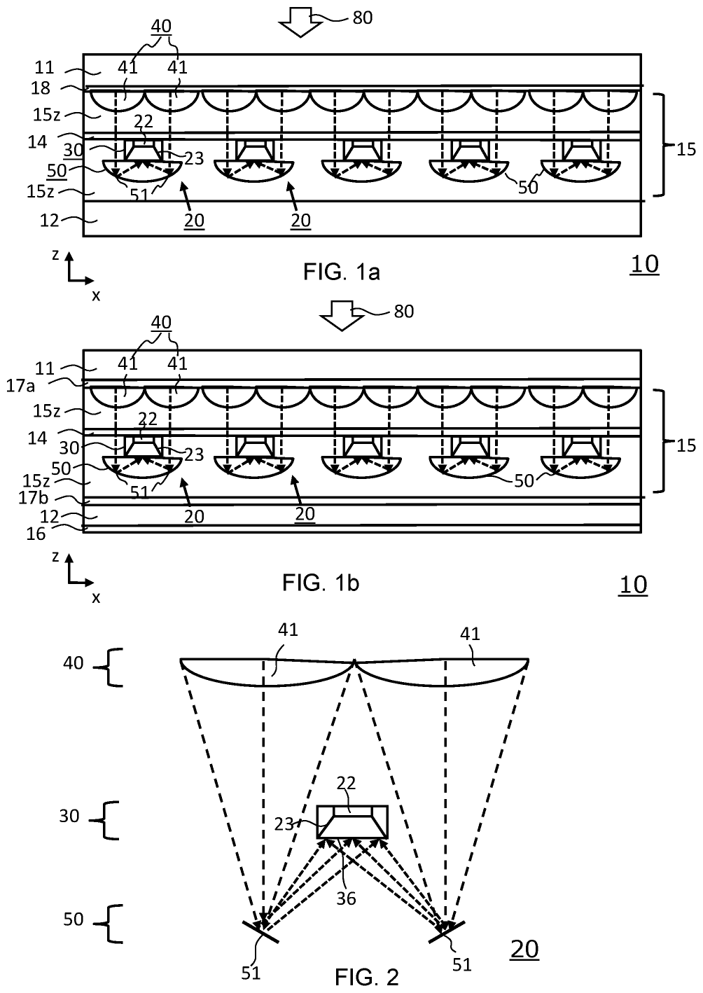

FIG. 1a shows a cross-sectional view of an energy generating photovoltaic component 10 in an x-z plane according to an embodiment of the invention. The energy generating photovoltaic component 10 has an outer pane 11 and an inner pane 12. According to embodiments, the outer pane 11 and the inner pane 12 may be made of glass or of plastic. According to embodiments, the outer pane 11 has a high transmission in the desired wavelength range and may in particular be a clear glass pane or a non-colored plastic pane. According to embodiments, the inner pane 12 can also be designed with high transmission and can be designed as a clear glass pane or as a non-colored plastic pane.

According to embodiments of the invention, the outer pane has a transmittance of more than 80%, in particular of more than 90%. Here, the transmittance refers in particular to the spectral range visible to the human eye, i.e. in particular to light with a wavelength between 380 and 780 nanometers (nm). The transmittance can also be referred to as light transmission.

According to embodiments of the invention, the outer pane 11 and the inner pane 12 may be made of glass, such as soda-lime silicate glass, borosilicate glass, aluminosilicate glass, or plastic, such as polycarbonate or PMMA. According to embodiments of the invention, the outer pane 11 and the inner pane 12 may have different thicknesses, and the outer glass pane 11 and the inner glass pane 12 may be designed with or without thermal or chemical bias. According to an embodiment, both the first pane and the second pane may be made of glass. According to another embodiment, the first pane may be made of glass and the second pane may be made of plastic. According to another embodiment, the second pane may be made of glass and the first pane may be made of plastic. According to an embodiment, both the first pane and the second pane may be made of plastic.

An energy generating layer 15 is provided between the outer pane 11 and the inner pane 12. The energy generating layer 15 has a plurality of concentrator photovoltaic modules 20. The concentrator photovoltaic modules 20 include a condenser optic 40 as a primary optic. The condenser optic 40 of the concentrator photovoltaic modules 20 each have one or more condenser lenses 41 that are laterally offset from each other, i.e., offset from each other in the x-direction and/or the y-direction. In this embodiment, the condenser lenses 41 are arranged at the same height in the vertical z-direction. According to other embodiments of the invention, however, it is also possible for the condenser lenses 41 to be arranged vertically, i.e. offset from one another in the z-direction.

The condenser lenses 41 collect or focus the light incident through the outer pane 11 and they can therefore also be referred to as collecting lenses. According to embodiments, the condenser lenses 41 can be bi-convex, plano-convex or concave-convex.

The concentrator photovoltaic modules 20 also have a partially transparent deflection optic 50 as a secondary optic, and a photovoltaic chip 22 integrated into a surface mountable housing 30. The surface mountable housing 30 comprises a transparent cover 36 (see FIG. 7) and an integrated reflector 23 as a tertiary optic. The condenser optic 40 are arranged in the vertical direction, i.e., in the z-direction, between the outer pane 11 and the photovoltaic chip 22. The partially transparent deflection optic 40 is arranged in the vertical direction, i.e. in the z-direction, between the photovoltaic chip 22 and the inner pane 12.

The transparent cover 36 and an entrance opening 23a (see FIG. 7) of the integrated reflector 23 disposed below the transparent cover face the inner glass pane 12. In other words, the photovoltaic chip 22 is arranged downward or the optical opening of the surface mountable housing 30 and the photovoltaic chip 22 is directed downwards towards the inner glass pane 11.

In solar operation, the condenser optic is configured to focus incident sunlight 80 through the outer pane 11 onto the deflection optic 50, in particular onto deflection regions 51 of the deflection optic 50. In this embodiment, the condenser lenses 41 have a concentric central plane and focus the incident light onto annular deflection regions 51 of the deflection optic 50. The deflection regions 51 are laterally offset from the housing 30, and the condenser optic 40 directs the incident light laterally past the housing 30 onto the deflection regions 51.

The deflection regions 51 of the deflection optic 50 can be designed in particular as reflecting or mirroring surfaces. The deflection optic 50 deflects the sunlight focused by the condenser optic 40 onto the deflection regions 51 into the integrated reflector 23. The corresponding beam path of the incident light is shown as a dashed line in FIG. 1. It should be noted here that the illustration of the beam path is roughly schematic to illustrate the principle.

The integrated reflector 23 concentrates or collects the sunlight deflected by the deflection optic 50 onto the photovoltaic chip 22.

The energy-generating layer 15 comprises a contacting layer 14 with conductor tracks. The contacting layer 14 can be formed, for example, as a printed circuit board, in particular as a flexible printed circuit board, and in particular as a flexible as well as transparent foil. The contacting foil 14 may be formed as a heat dissipating foil.

The surface mountable housings 30 can be arranged on the contacting layer 14 by soldering, in particular by reflow soldering, and electrically connected to the photovoltaic chips 22.

According to embodiments of the invention, the energy generating layer 15 or the interstices 15z of the energy generating layer 15 may be filled with transparent plastic. According to other embodiments of the invention, the energy-generating layer 15 or the interstices 15z of the energy-generating layer 15 can be formed as a vacuum.

A protective layer 18 is provided between the outer pane 11 and the energy generating layer 15 to protect against ultraviolet (UV) radiation. In particular, this protective layer protects the elements of the energy generating layer, e.g., the surface mountable housing 30, the contacting layer 14, the condenser optic 40 and the deflection optic 50 from the UV radiation. This is particularly advantageous in embodiments, where the elements of the energy generating layer 15 are made of or comprise plastic. The UV protective layer 18 protects the plastic from aging.

According to an embodiment, the protective layer 18 can be formed as a foil. According to another embodiment, a coating of the outer pane 11 can be provided as a UV protective layer.

FIG. 1b shows a cross-sectional view of an energy-generating photovoltaic component 10 in an x-z plane according to another embodiment of the invention. The photovoltaic component 10 corresponds to a large extent to the photovoltaic component 10 of FIG. 1a.

According to the embodiment of FIG. 1b, the energy generating layer 15 is integrated between the outer pane 11 and the inner pane 12 by means of an outer composite layer 17a and an inner composite layer 17b. The composite layers 17a, 17b can be formed in particular as lamination foils and can be made of plastic, e.g. PVB or EVA. Such composite layers facilitate the production of the energy-generating photovoltaic component.

According to a further embodiment of the invention, the photovoltaic components 10 may also have further layers, in particular foils. Thus, according to embodiments of the invention, a heat-absorbing foil or a heat-dissipating foil can be arranged behind or below the energy-generating layer 15.

According to embodiments, the foils can be transparent or partially transparent and can be applied as a lamination foil. According to embodiments, the photovoltaic components 10 can be provided with an anti-scratch coating in the case of plastic and/or a low-E coating in the case of glass, which is exemplarily shown as layer 16 in FIG. 1b.

FIG. 2 shows an enlarged view of a concentrator photovoltaic module 20 according to an embodiment of the invention with an exemplary beam path. The condenser lenses 41 of the condenser optic 40 focus the incident light onto the deflection regions 51 of the deflection optic 50. Then, the incident light is reflected by the deflection regions 51 in the direction of the surface-mountable housing 30, in particular onto its transparent cover, and is guided by the integrated reflector 23 onto the photovoltaic chip 22. Thereby, according to the examples of FIGS. 1a, 1b and 2, a single-stage deflection is shown.

According to other embodiments, however, multi-stage deflection may also be performed by the deflection optic 50.

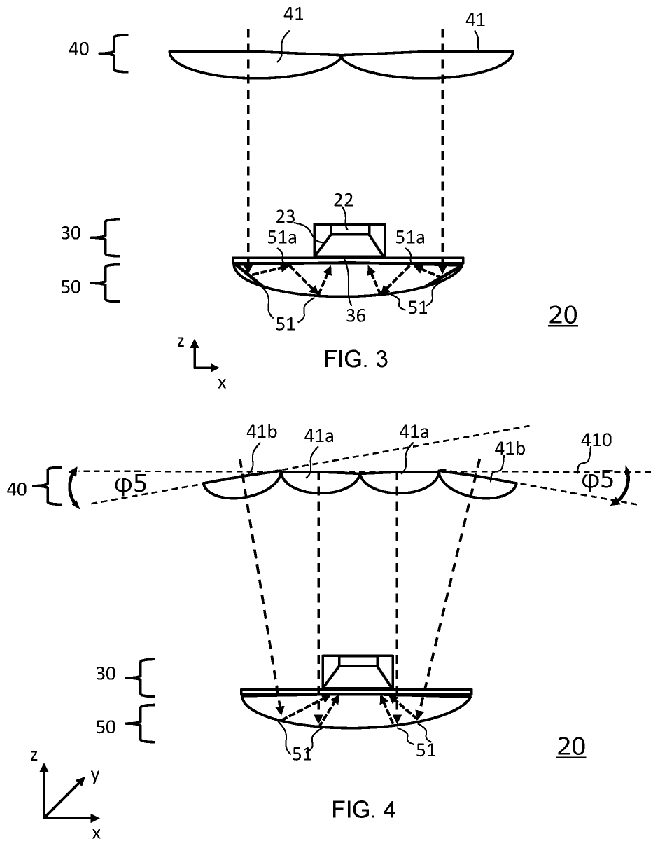

For example, FIG. 3 shows an enlarged view of a concentrator photovoltaic module 20 according to an embodiment of the invention with a multi-stage deflection or reflection. For this purpose, the deflection optic 50 has a plurality of deflection or reflection regions 51.

According to embodiments, the deflection of the deflection optic 50 can be implemented in a wide variety of ways. In addition to providing reflective or mirroring surfaces, for example reflective coatings or mirrors, the deflection optic according to embodiments can also be designed as an optical waveguide or comprise an optical waveguide. In particular, mixed forms can also be provided. Thus, according to embodiments, reflection regions may be provided which receive the focused light from the condenser optic 40 and then reflect or couple it into an optical waveguide which passes the light to the reflector of the housing 30.

According to embodiments, the deflection optic 50 can consist of a base body made of transparent plastic or glass. According to embodiments, the reflective deflection regions 51 are then integrated in such a base body made of glass or plastic, e.g. by means of reflective coatings. According to embodiments, the effect of total reflection can also be exploited at the boundary surfaces of the deflection optic according to embodiments. In FIG. 3, this is possible in particular at the upper deflection regions 51a, on which the light impinges at a flat angle. According to embodiments, the effect of total internal reflection can be implemented by coatings on the surface of the deflection optic 50, for example by providing coatings with a low refractive index.

FIG. 4 shows a concentrator photovoltaic module 20 having a plurality of condenser lenses, namely two condenser lenses 41a, 41b, arranged side by side. In this regard, the outer condenser lens 41b is arranged inclined at an angle φ5, which may also be referred to hereinafter as the fifth angle, with respect to the horizontal x-y plane 410 of the photovoltaic component 10 or concentrator photovoltaic module 20. The inner lens 41a is arranged parallel to the horizontal plane 410 of the photovoltaic component 10 or the concentrator photovoltaic module 20.

It should be noted here that the term horizontal plane of the photovoltaic component 10 or concentrator photovoltaic module refers to the base surface or bottom surface of the photovoltaic component or concentrator photovoltaic module, and in particular should be parallel to the base surface and thus parallel to the inner pane 12 and the outer pane 11. Due to the inclined arrangement of the outer condenser lenses 41b, it is possible to use the sunlight in an improved manner even at low elevation, e.g. in the morning and in the evening.

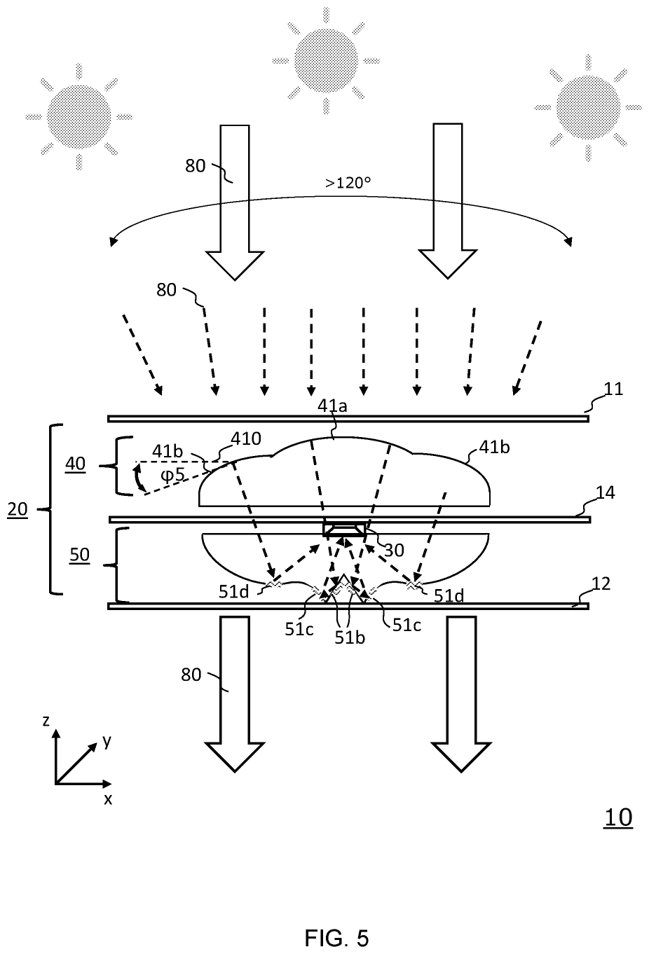

FIG. 5 shows a cross-sectional view of an energy generating photovoltaic component 10 in an x-z plane according to an embodiment of the invention. The energy generating photovoltaic component 10 has an outer pane 11 and an inner pane 12. According to embodiments, the outer pane 11 and the inner pane 12 may be made of glass or of plastic.

A plurality of concentrator photovoltaic modules 20 are arranged between the outer pane 11 and the inner pane 12, although only one concentrator photovoltaic module 20 is shown in FIG. 5 for ease of illustration. The concentrator photovoltaic modules 20 include a condenser optic 40 as the primary optic. The condenser optic 40 of the concentrator photovoltaic modules 20 include an inner lens 41a, which is centrally located above the housing 30. Adjacent to this is an outer lens 41b which concentrically surrounds the inner lens 41a.

Here, the outer condenser lens 41b is arranged inclined at an angle φ5 with respect to the horizontal x-y plane of the photovoltaic component 10 (and thus also with respect to the panes 11, 12). The inner lens 41a is arranged parallel to the horizontal plane 410 of the photovoltaic component 10 or the concentrator photovoltaic module 20. Thus, according to embodiments, the incident sunlight can be captured in a range of more than 120°.

The concentrator photovoltaic modules 20 also include a partially transparent deflection optic 50 as a secondary optic and a photovoltaic chip 22 integrated into a surface mountable housing 30.

In solar operation, the condenser optic 40 is configured to focus sunlight 80 incident through the outer pane 11 onto the deflection optic 50. According to this embodiment, the inner lens 41a focuses the light onto central deflection regions 51b. From these, it is reflected onto deflection regions 51c and from there towards the housing 30 and the reflector 23. The outer lens 41b focuses the light onto outer deflection regions 51d. From these, the light is reflected toward the housing 30 and the reflector 23. The deflection regions 51b, 51c and 51d are shown in FIG. 5 as a wave pattern, and they may be designed in particular as reflective or specular surfaces. The corresponding beam path of the incident light is again shown roughly schematically in dashed form in FIG. 5.

According to embodiments, the deflection regions 51, in this example the deflection regions 51b, 51c and 51d, cover a maximum of 20%, in particular a maximum of 15%, of the horizontal cross-sectional area (in the x-y plane) of the photovoltaic component 10. Thus, according to embodiments of the invention, it is possible to achieve a light transmittance or transparency of the photovoltaic component of more than 50% and preferably of more than 75%, in particular related to the spectral range of sunlight visible to humans.

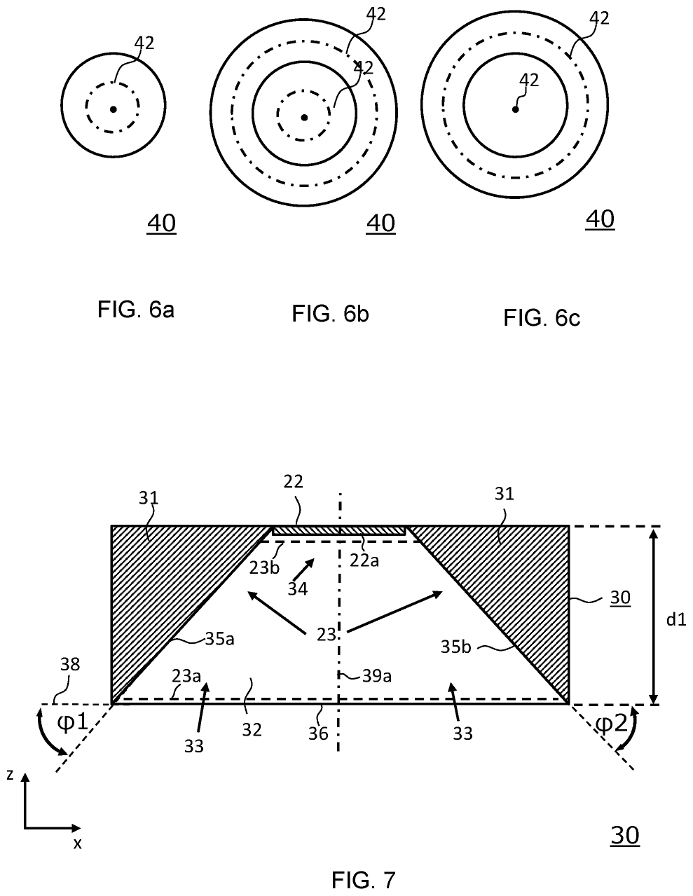

FIG. 6a shows a top view of a condenser optic 40, which is designed according to FIGS. 1a, 1b, 2 and 3. The dash-dot line 42 indicates the center plane of the lenses.

FIG. 6b shows a top view of a condenser optic 40, which is designed according to FIG. 4. The dash-dot lines 42 indicate the center planes of the lenses.

FIG. 6c shows a top view of a condenser optic 40, which is designed according to FIG. 5. The dash-dot line 42 and the dot 42 indicate the center plane of the lenses.

FIG. 7 shows a cross-sectional view of the surface mountable housing 30 in an x-z plane according to an embodiment of the invention. According to this embodiment, the photovoltaic chip 22 is arranged symmetrically with respect to a vertical plane of symmetry 39a of the housing 30.

The housing 30 comprises a base body 31. The base body 31 can be made in particular of plastic and can be produced, for example, by means of an injection molding process. The housing 30 or the base body 31 has a recess 32. The recess 32 forms or establishes a receiving tray 33 with a recessed bottom portion 34 for receiving the photovoltaic chip 22. According to preferred embodiments of the invention, the photovoltaic chip 22 is designed as a multi-junction solar cell, but according to other embodiments of the invention, it can also be designed as a single-junction solar cell. According to embodiments of the invention, a photovoltaic chip means in particular a photovoltaic DIE, i.e. an unhoused piece of a semiconductor wafer with a multi-junction or single-junction solar cell.

The housing 30 comprises at least two electrical contacts for contacting the photovoltaic chip 22, which are not shown in FIG. 7 to simplify the illustration. The housing 30 further has a transparent cover 36 which closes the housing 30 and in particular the recess 32, in particular seals it in a waterproof and dustproof manner.

According to embodiments, the transparent cover 36 is made of glass, in particular thin glass or ultra-thin glass. Preferably, the housing 30 is protected against solid foreign bodies and against liquids by means of the transparent cover 36. For this purpose, housing 30 may be designed in particular in accordance with IP protection class 66. According to embodiments, housing 36 has a scope of protection according to the International Protection (IP) code against solid foreign bodies of at least 4 and a scope of protection against liquids of at least 4. The transparent cover 36 can be attached to the housing 30, in particular to the base body 31, by means of ultrasonic welding, for example.

The receiving tray 33 includes side walls having reflective regions 35a and 35b. The receiving tray 33 forms a reflector 23 by means of the reflective regions. The reflector 23 represents a tertiary optic of the concentrator photovoltaic module 20 and is configured to function as a light collector or optical homogenizer. According to embodiments, the reflector 23 may be a conical cylinder or a conical cuboid. The reflector 23 has an entrance opening or entrance aperture 23a below the transparent cover 36. Furthermore, the reflector 23 has an exit opening or exit aperture 23b through which the light falls onto the photovoltaic chip 22. The entrance opening 23a and the exit opening 23b are schematically shown by dashed lines.

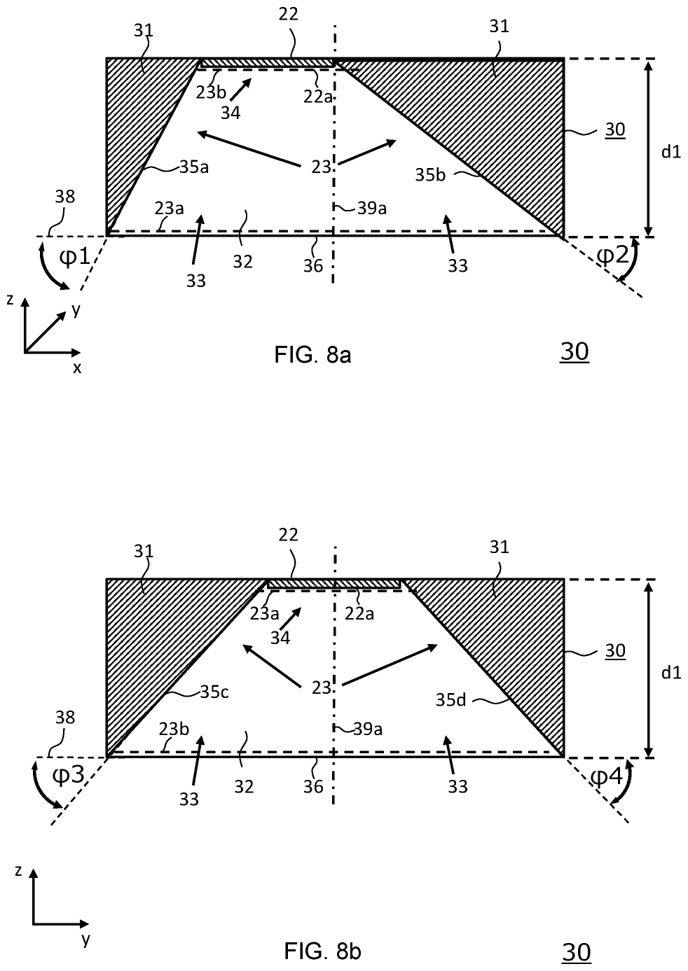

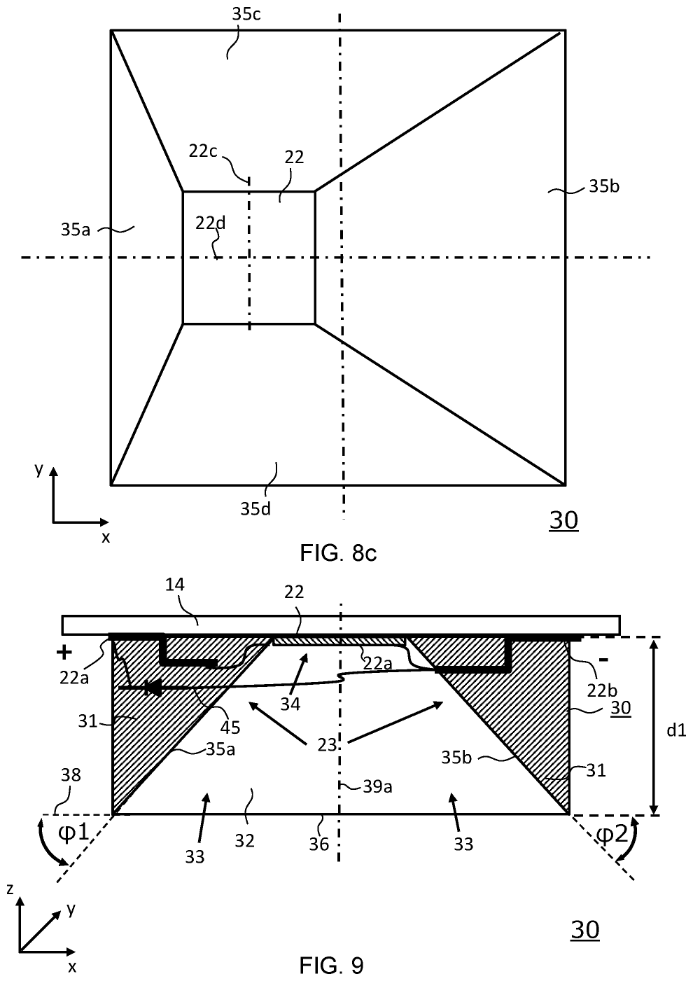

FIG. 8a shows a cross-sectional view of a surface mountable housing 30 in an x-z plane according to another embodiment of the invention. FIG. 8b shows a cross-sectional view of the surface mountable housing 30 in a y-z plane perpendicular to the x-z plane. FIG. 8c shows a top view on the surface mountable housing in the x-y plane.

The surface mountable housing 30 is similar in structure to the housing 30 shown in FIG. 7, and accordingly has a base body 31 and a recess 32 forming a receiving tray 33 with a recessed bottom portion 34 for receiving the photovoltaic chip 22.

The receiving tray 33 includes sidewalls having a first reflective region 35a, a second reflective region 35b, a third reflective region 35c, and a fourth reflective region 35d. The first reflective region 35a is oriented at a first angle φ1 with respect to a horizontal x-y plane 38 of the housing 30. The second reflective region 35b is oriented at a second angle φ2 with respect to the horizontal x-y plane 38 of the housing 30. The third reflective region 35c is oriented at a third angle φ3 with respect to the horizontal x-y plane 38 of the housing 10. The fourth reflective region 35d is oriented at a fourth angle φ4 with respect to the horizontal x-y plane 38 of the housing. According to the embodiment illustrated in FIGS. 8a to 8c, the first angle φ1 is different from the second angle φ2, while the third angle φ3 and the fourth angle φ4 in this example are the same size or approximately the same size. According to other embodiments, the third angle φ3 and the fourth angle φ4 may also be of different sizes.

In particular, as shown in FIGS. 8a and 8b, the photovoltaic chip 22 is arranged asymmetrically with respect to the vertical plane of symmetry 39a of the housing 30, while it is arranged symmetrically with respect to the vertical plane of symmetry 39b of the housing 30.

As can be seen in particular from FIGS. 8a and 8c, the first reflective region 35a and the second reflective region 35b are opposite to each other with respect to the photovoltaic chip 22, in particular with respect to a first vertical plane of symmetry 22c of the photovoltaic chip 22 shown in FIG. 8c.

According to the example shown, the first angle φ1 is approximately 65° and the second angle φ2 is approximately 35°.

According to embodiments of the invention, the angles φ1, φ2, φ3 and φ4 are in a range between 0° and 110°. According to preferred embodiments of the invention, the first angle φ1 is in a range between 45° and 110°, in particular in a range between 60° and 90°, and is thus relatively steep, while the second angle φ2 is in a range between 0° and 45°, in particular in a range between 10° and 35°, and is thus relatively flat.

Such a design is advantageous, for example, for photovoltaic modules intended for vertical installation. This makes it possible to significantly improve the power yield of the photovoltaic module when installed vertically, in particular because the “lower” reflective surface is more inclined with respect to the horizontal plane of the housing than the “upper” reflective surface.

According to embodiments, the first reflective region 35a, the second reflective region 35b, the third reflective region 35c, and the fourth reflective region 35d are applied as a coating to the base body 31 of the receiving tray 33.

According to other embodiments, the first reflective region 35a, the second reflective region 35b, the third reflective region 35c and the fourth reflective region 35d are formed as a reflective foil, which can be applied to the base body 31 of the receiving tray 33, for example, by means of adhesive or other processes.

According to the embodiments shown in FIGS. 8a to 8c, the reflective regions 35a, 35b, 35c and 35d are each formed as planar surfaces, in particular as trapezoidal surfaces.

However, according to other embodiments not shown, the reflective regions 35a, 35b, 35c, and 35d may have other shapes, particularly concave shapes and convex shapes.

A module designed in this way allows the angles φ1, φ2, φ3 and φ4 of the reflective regions 35a 35b, 35c and 35d to be selected individually and differently in each case and to be adapted to the respective orientation of the modules to the surfaces intended for installation and the corresponding solar exposure of the modules in terms of elevation and/or azimuth.

FIG. 9 shows a cross-sectional view of a surface mountable housing 30 in an x-z plane according to an embodiment of the invention. In FIG. 9, the electrical connections of the module are shown in more detail. In particular, the surface mountable housing 30 has a first electrical contact 22a and a second electrical contact 22b. The electrical contacts 22a, 22b are arranged on opposite sides of the housing 30 and are formed as so-called leads, which are embedded in the base body 31 made of plastic. The photovoltaic chip 22 is electrically connected to the leads of the electrical contacts 22a and 22b by means of wire bonding. Thus, the module 20 is formed as a surface mountable module in SMD-technology (Surface Mount Technology). The module 20 comprises also a bypass diode 45 integrated into the housing 30, which can be designed in particular as a Schottky diode. The bypass diode is connected in parallel with the photovoltaic chip 22 and accordingly connected on the one hand to the electrical contact 22a and on the other hand to the electrical contact 22b, also according to embodiments by means of wire bonding. The photovoltaic chip 22 can, for example, be electrically contacted with conductor tracks of the contacting layer 14 by means of soldering.

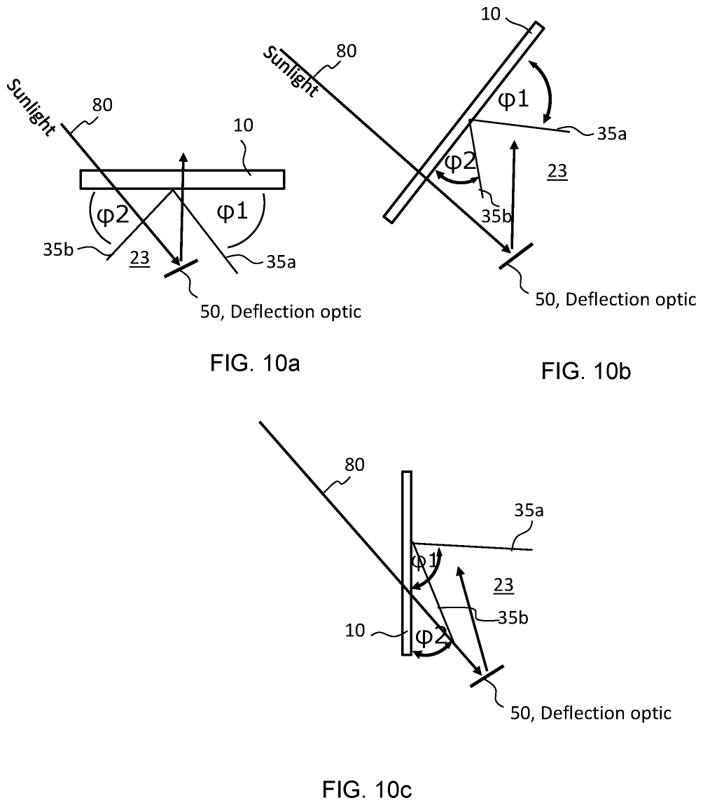

FIGS. 10a to 10c show various installation situations of photovoltaic components 10 and the surface-mountable housings integrated therein. The angles φ1 and φ2 refer to the angles of the reflection surfaces 35a, 35b of the reflectors 23 integrated in the housings 30.

In FIGS. 10a to 10c, the position of the sun 80 is shown in an exemplary manner, for example, at the noon time.

In addition, the course of the reflecting surfaces 35a, 35b of the reflectors 23 is shown in an exemplary schematic manner by means of simple lines in FIGS. 10a to 10c. In addition, the deflection optic 50 is shown as an example, which reflects the incident sunlight 80 into the reflector 23.

FIG. 10a shows a photovoltaic component 10 intended for predominantly horizontal installation in a building or device, for example as a horizontal roof photovoltaic component. FIG. 10b shows a photovoltaic component 10 which is intended for inclined installation positions, for example between 20° and 80°, e.g. for pitched roofs.

FIG. 10c shows a photovoltaic component 10 intended for primarily vertical installation in a building or device.

According to embodiments of the invention, the first angle φ1 and the second angle φ2 can each be individually adapted to the respective installation situation in order to optimize the light capture of the reflector 23 for the respective installation situation. While in a horizontal installation situation the first angle φ1 and the second angle φ2 are preferably selected to be the same size, in an inclined and a vertical installation situation the first angle φ1 and the second angle φ2 are preferably selected to be different in order to increase the light capture with respect to the elevation of the solar radiation.

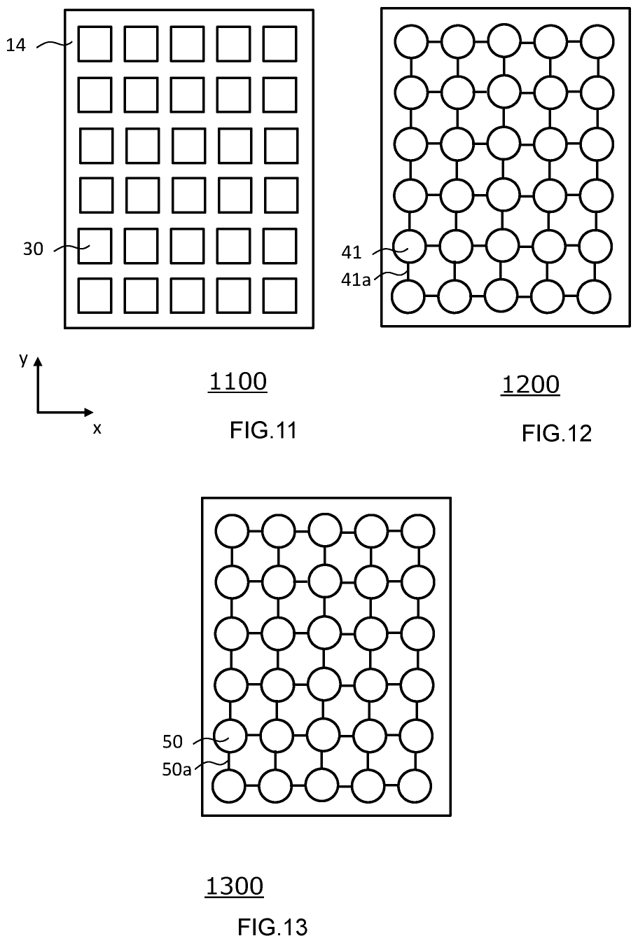

FIG. 11 shows a top view of a photovoltaic chip array 1100. The photovoltaic chip array 1100 has a plurality of SMD housings 30 with integrated photovoltaic chips and reflectors, which are soldered as surface-mounted components on a printed circuit board or contacting layer 14 formed as a foil.

FIG. 12 shows a lens array 1200 according to an embodiment of the invention with a plurality of condenser lenses 41 arranged flatly in a plane. The lens array 1200 can be prefabricated, for example, by injection molding from transparent plastic. The individual condenser lenses 41 are connected by thin webs 41a. According to an embodiment, the lens array prefabricated in this way can be attached to the underside of the outer pane 11, e.g. by adhesive bonding.

FIG. 13 shows an array 1300 according to an embodiment of the invention with a plurality of deflection optics 50 arranged flatly in a plane. The deflection optics 50 are shown by circles as an example. The array 1300 can be prefabricated, for example, by means of injection molding from transparent plastic. The individual deflection optics 50 are connected by thin webs 50a. According to an embodiment, the array 1300 prefabricated in this way can be attached to the inner pane 12, e.g. by adhesive bonding.

According to another embodiment, the prefabricated lens array 1100 and the prefabricated array 1300 can each be attached to the photovoltaic chip array 1200 and then attached between the panes 11, 12 as an overall prefabricated module.

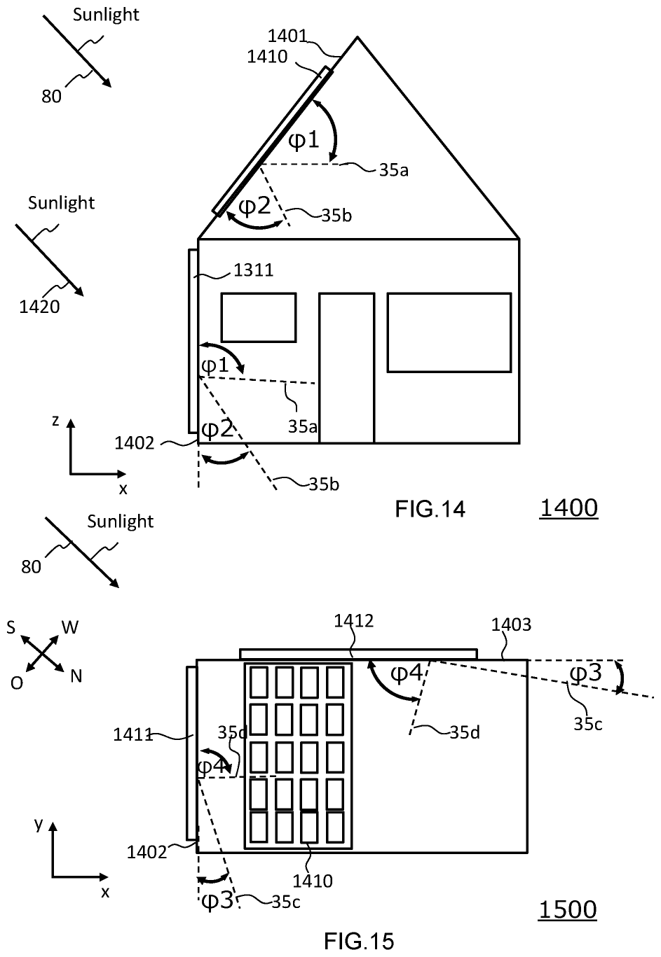

FIG. 14 shows a side view of a building or house 1400. The building 1400 has a photovoltaic component 1410 on a pitched roof 1401 and a photovoltaic component 1411 on a vertical side wall 1402, which may be configured like the photovoltaic components 10 described above.

FIG. 15 shows a top view of the building 1400, showing that in addition to the photovoltaic component 1410 and the photovoltaic component 1411, the building 1400 includes another photovoltaic component 1412 on the back wall 1403.

In FIGS. 14 and 15, the position of the sun 80 is shown in an exemplary manner, e.g., at the noon time.

Moreover, in FIG. 14, the first angle φ1 and the second angle φ2 of the reflectors 23 of the individual photovoltaic components 1410 and 1411 are shown in an exemplary manner by means of dashed lines.

Furthermore, in FIG. 15, the third angle φ3 and the fourth angle φ4 of the reflectors 23 of the individual photovoltaic components 1410 and 1412 are shown in an exemplary manner by means of dashed lines.

The angles φ1, φ2, φ3 and φ4 again refer to the angles of the reflection surfaces of the reflectors 23 of the concentrator photovoltaic modules of the individual photovoltaic components integrated into the housings 30.

In the example of FIGS. 14 and 15, the individual photovoltaic components 1410, 1411 and 1412 each have different combinations of the individual angles φ1, φ2, φ3 and φ4. This makes it possible to take into account the respective installation situation of the systems 1410, 1411 and 1412 and to optimally adapt the angles φ1, φ2, φ3 and φ4 to the position of the sun or the course of the sun in order to achieve a maximum concentration effect or amplification of the reflector 23.

According to embodiments of the invention, the first angle φ1 and the second angle φ2 are selected in particular so that they optimally take into account the respective installation situation with respect to the elevation of the sun.

According to embodiments of the invention, the third angle φ3 and the fourth angle φ4 are in particular selected in such a way that they optimally take into account the respective installation situation with respect to the azimuth of the sun. Thus, FIG. 15 also shows the orientation of the house with respect to the cardinal directions. Exemplarily, the house wall 1402 has a southeast exposure and the back wall 1403 has a southwest exposure. By appropriately and individually choosing the angles φ3 and φ4 for the side wall 1402 and the back wall 1403, the efficiency of the photovoltaic component can be improved.

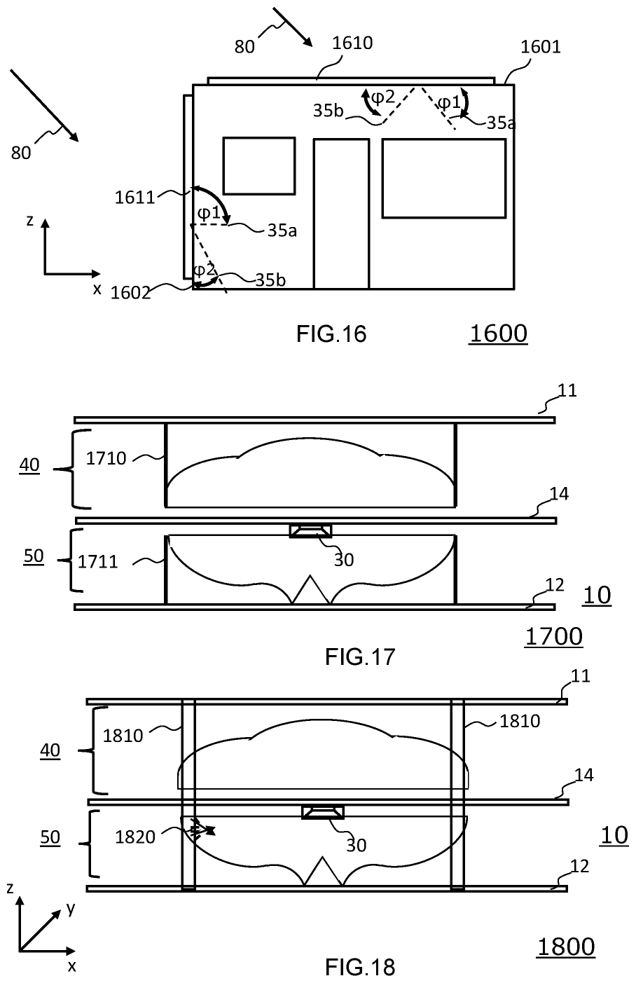

FIG. 16 shows a side view of a house 1600 with a flat roof 1601. A photovoltaic component 1610 is mounted on the flat roof 1601 and a photovoltaic component 1611 is mounted on a vertical side wall 1602.

The first angle φ1 and the second angle φ2 of the photovoltaic component 1610 are selected differently from the first angle φ1 and the second angle φ2 of the photovoltaic component 1410 of the pitched roof shown in FIG. 14 to improve the reflective effect of the photovoltaic components.

Thus, according to embodiments of the invention, the photovoltaic components 10 can be used as energy-generating glass or plastic components for roof systems, flat roofs, industrial roofs, house roofs, facades, facade structures, and/or as single or multi-pane insulating glasses.

FIG. 17 shows a cross-sectional view 1700 of an energy-generating photovoltaic component 10 in an x-z plane according to a further embodiment of the invention. In particular, the energy-generating photovoltaic component 10 is configured as described in FIG. 5. According to this embodiment, the condenser optic 40 is attached or supported to the outer pane 11 by means of webs 1710. Furthermore, the deflection optic 50 is attached to or supported on the inner pane 12 by means of webs 1711. The webs can be made in particular of plastic. According to embodiments, the webs 1710 and 1711 can also be connected or formed in one piece.

FIG. 18 shows a cross-sectional view 1800 of an energy-generating photovoltaic component 10 in an x-z plane according to a further embodiment of the invention. In particular, the energy generating photovoltaic component 10 is configured as described in FIG. 5. According to this embodiment, the condenser optic 40 and the deflection optic 50 are fixed or supported between the outer pane 11 and the inner pane 12 by means of webs 1810. In this case, the webs 1810 are configured as optical waveguides and are configured to guide or couple out light incident through the inner pane 12 and the outer pane 11 into the deflection optic 50. For this purpose, the optical waveguides 1810 include decoupling devices 1820. In this way, the efficiency can be further increased. In addition, in such an embodiment it is also possible to design the deflection optic also, at least partially, as an optical waveguide.

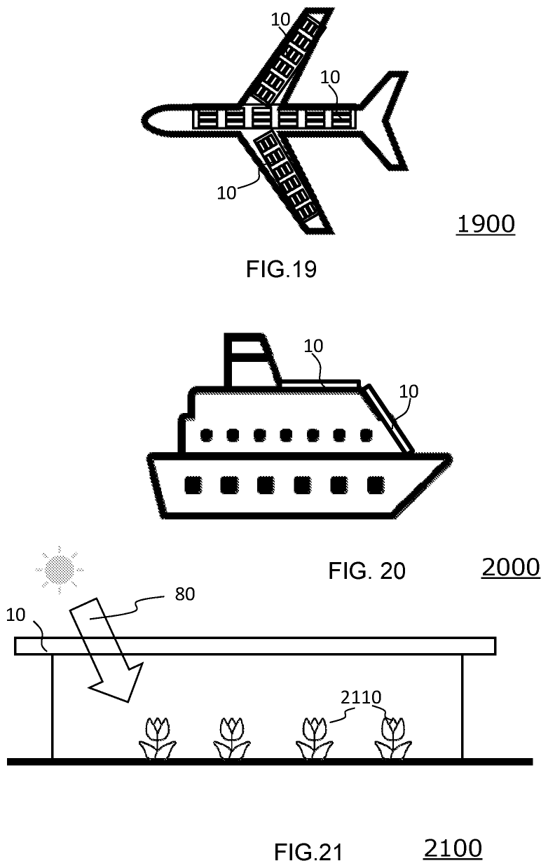

FIG. 19 shows an aircraft 1900 with multiple photovoltaic components 10 integrated into the outer skin of the aircraft 1900.

FIG. 20 shows a ship 2000 with a plurality of photovoltaic components (10) disposed on the surface of the ship.

FIG. 21 shows a photovoltaic component 10, which is arranged above an agricultural area 2110. As a result of the partially transparent design of the photovoltaic component 10, it is thus possible to use the agricultural areas 2110 both for the generation of solar energy and further for the cultivation of plants, vegetables, fruit, etc.

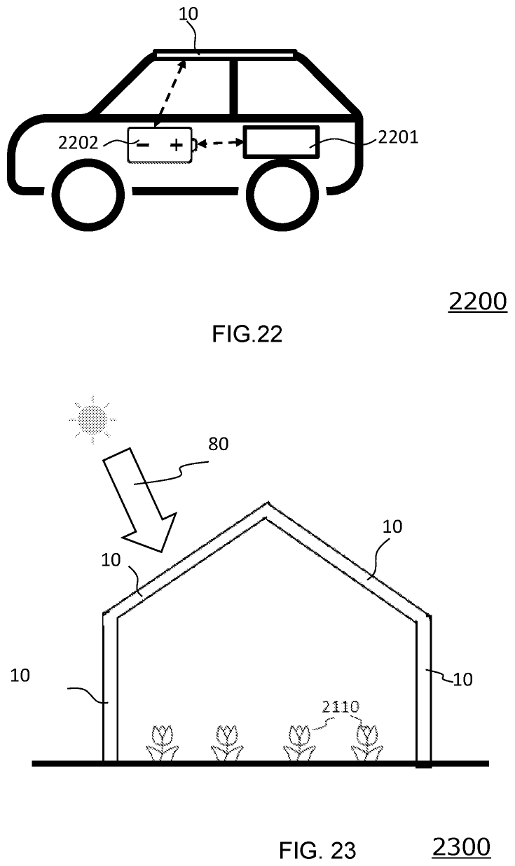

FIG. 22 shows an automobile 2200 according to an embodiment of the invention. The automobile 2200 has one or more photovoltaic components 10, e.g. as roof windows or roof glazing. In particular, the automobile may be configured as an electric vehicle or as a hybrid vehicle or as a fuel cell vehicle and accordingly has at least one electric drive, e.g., electric motor 2201 and at least one battery 2202. The photovoltaic components 10 are configured, for example, to charge the battery 2202. According to a further embodiment of the invention, the vehicle 2200 may also be configured without an electric drive and have, for example, only an internal combustion engine or other drive. In such a case, the photovoltaic components 10 can be used to feed solar energy into the on-board electrical system and thus supply the electrical loads or to charge a low-voltage battery for operating the vehicle electrical system.

FIG. 23 shows a greenhouse 2300 whose roof surfaces and side surfaces are formed by photovoltaic components 10 according to embodiments of the invention. As a result of the partially transparent design of the photovoltaic components 10, it is thereby possible to use the greenhouses both for the generation of solar energy and for the cultivation of plants, vegetables, fruit, etc.

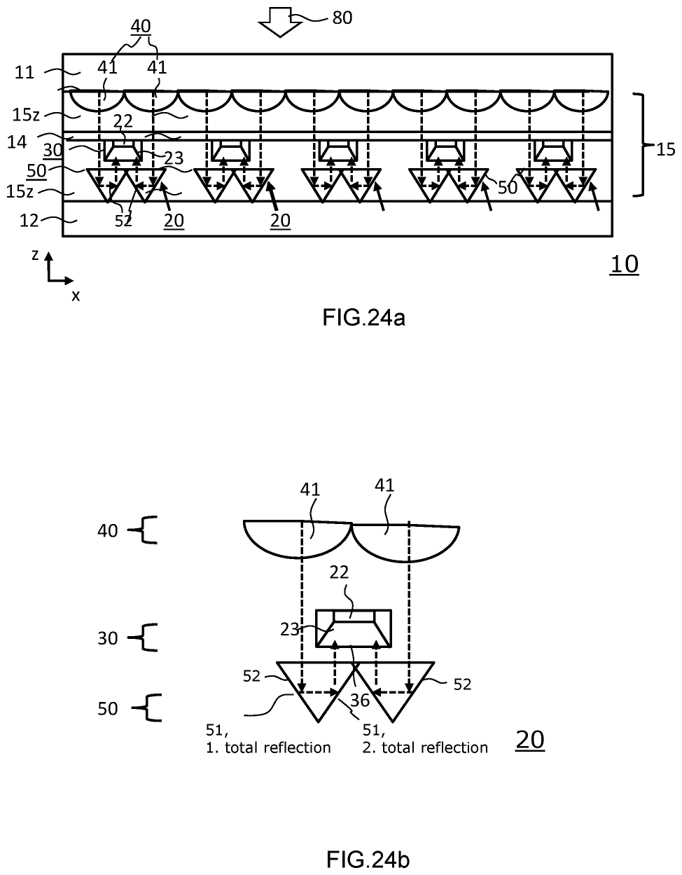

FIG. 24a shows a cross-sectional view of an energy generating photovoltaic component 10 in an x-z plane according to another embodiment of the invention. The photovoltaic component 10 corresponds in large part to the photovoltaic component 10 of FIG. 1a. In the embodiment of FIG. 24a, the deflection optic 50 each have two prisms 52 that deflect the incident light toward the surface-mountable housing 30 by means of total reflection twice. In the process, the direction of the incident light is reversed. The prisms 52 may therefore also be referred to as reversing prisms.

FIG. 24b shows an enlarged view of a concentrator photovoltaic module 20 according to an embodiment of the invention with an exemplary beam path. The condenser lenses 41 of the condenser optic 40 focus the incident light onto first deflection regions 51a of the prisms 52. Then the incident light is reflected by means of total internal reflection from the first deflection regions 51a in the direction of second deflection regions 51b. There, a renewed (second) total reflection takes place in the direction of the surface-mountable housing 30, in particular on its transparent cover. In FIG. 24b, only the parallel incident center beam is shown. The prisms 52 are preferably designed in such a way that also somewhat obliquely incident beams are deflected in the direction of the surface-mountable housing 30.

According to further embodiments of the invention, the photovoltaic components 10 may also be integrated or attached to construction vehicles, agricultural vehicles, trains, or containers.

While preferred embodiments of the invention are described in the present application, it should be clearly noted that the invention is not limited to these and may be carried out in other ways as well within the scope of the following claims.

1. Photovoltaic component (10), comprising,
an outer pane (11); and
an inner pane (12);
characterized in that
an energy generating layer (15) comprising a plurality of concentrator photovoltaic modules (20) is arranged between the outer pane (11) and the inner pane (12), the concentrator photovoltaic modules (20) comprising
a condenser optic (40) as the primary optic;
a partially transparent deflection optic (50) as secondary optic; and
a photovoltaic chip (22) integrated into a surface mountable housing (30), the surface mountable housing (30) having a transparent cover (36) and an integrated reflector (23) as a tertiary optic; wherein
the condenser optic (40) is arranged between the outer pane (11) and the photovoltaic chip (22);
the partially transparent deflection optic (50) is arranged between the photovoltaic chip (22) and the inner pane (12); and
the transparent cover (36) and an entrance opening (23a) of the integrated reflector (23) face the inner pane (12).

2. Photovoltaic component according to claim 1, wherein
the condenser optic (40) is configured to focus sunlight incident through the outer pane (12) onto one or more deflection regions (51) of the deflection optic (50);
the deflection optic (50) is configured to deflect the sunlight focused by the condenser optic (40) onto the one or more deflection regions (51) into the integrated reflector (23); and
the reflector (23) is configured to concentrate the sunlight deflected by the deflection optic (50) onto the photovoltaic chip (22).

3. Photovoltaic component according to claim 1, characterized in that at least one of the one or more deflection regions (51) is arranged laterally offset from the surface-mountable housing (30).

4. Photovoltaic component according to claim 1, characterized in that
the deflection optic (50) is configured to perform a multi-stage deflection of the sunlight into the integrated reflector (23).

5. Photovoltaic component according to claim 1, wherein
the one or more deflection regions (51) are designed as reflective surfaces.

6. Photovoltaic component according to claim 1, characterized in that the deflection optic (50) comprises an optical fiber.

7. Photovoltaic component according to claim 1, characterized in that the photovoltaic component (10) has a light transmission of more than 50%, in particular of more than 75%.

8. Photovoltaic component according to claim 1, characterized in that the deflection region or the deflection regions (51) of the deflection optic cover a maximum of 20%, in particular a maximum of 15%, of the horizontal cross-sectional area of the photovoltaic component (10).

9. Photovoltaic component according to claim 1, characterized in that the condenser optic (40) of the concentrator photovoltaic modules (20) comprise a plurality of condenser lenses (41) arranged side by side;
wherein the condenser lenses (41) are arranged in particular rotationally symmetrical to a central axis of the concentrator photovoltaic module.

10. Photovoltaic component according to claim 1, characterized in that the condenser optic (40) of the concentrator photovoltaic modules (20) comprises a plurality of condenser lenses (41) arranged side by side, wherein at least one of the condenser lenses (41b) is arranged inclined at an angle, in particular a fifth angle, with respect to a horizontal plane (410) of the photovoltaic component.

11. Photovoltaic component according to claim 10, characterized in that the condenser optic (40) of the concentrator photovoltaic modules (20) comprises a first condenser lens (41b) arranged inclined at the fifth angle with respect to the horizontal plane of the photovoltaic component and a second condenser lens (41a) arranged parallel to the horizontal plane of the photovoltaic component.

12. (canceled)

13. Photovoltaic component according to claim 1, wherein the concentrator photovoltaic modules (20) are integrated into a transparent plastic material.

14. Photovoltaic component according to claim 1, wherein the energy generating layer (15) is integrated between the outer and inner panes by means of an outer and an inner composite layer (17a, 17b) of plastic material.

15-16. (canceled)

17. Photovoltaic component according to claim 1, characterized in that the housing (30) comprises a recess (32) forming a receiving tray (33) with a recessed bottom portion (34) for receiving the photovoltaic chip (22), wherein
the receiving tray (33) has side walls with reflective regions (35a, 35b) which form the reflector (23).

18. Photovoltaic component according to claim 17, characterized in that
the receiving tray (33) has sidewalls with at least first and second reflective regions (35a, 35b), the first reflective region (35a) being oriented at a first angle (φ1) with respect to a horizontal plane (38) of the housing (30) and the second reflective region (35b) being oriented at a second angle (φ2) with respect to the horizontal plane (38) of the housing (30); and
the first angle (φ1) is different from the second angle (φ2).

19. Photovoltaic component according to claim 18, wherein the receiving tray (33) comprises side walls with a third and a fourth reflective region (35c, 35d), wherein the third reflective region (35c) is oriented at a third angle (φ3) with respect to the horizontal plane of the housing (30) and the fourth reflective region (35d) is oriented at a fourth angle (φ4) with respect to the horizontal plane of the housing (30), in particular wherein the third angle is different from the fourth angle.

20-23. (canceled)

24. Photovoltaic component according to claim 1, characterized in that
the condenser optic (40) is fixed or supported on the outer pane (11) by means of webs (1710); and/or
the deflection optic (50) is fixed or supported on the inner pane (12) by means of webs (1711), wherein the webs are designed as optical waveguides (1810).

25. (canceled)

26. Photovoltaic component according to claim 1, characterized in that the deflection optic (50) comprises one or more prisms (52).

27-30. (canceled)

31. Device or building comprising one or more photovoltaic components (10) according to any one of the preceding claims, wherein the device is in particular a vehicle, a container or a greenhouse.

32. Use of a photovoltaic component according to claim 1, for installation in or attachment to a building, a vehicle, a container, a greenhouse, and other devices or for arranging on agricultural land.

33. (canceled)
